(19) United States
(12) Patent Application Publication
(10) Pub. No.: US 2025/0365855 A1
(43) Pub. Date: Nov. 27, 2025

(54) MULTI-LAYERED PRINTED CIRCUIT BOARD ASSEMBLY AND ELECTRONIC DEVICE INCLUDING THE SAME

(71) Applicant: SAMSUNG ELECTRONICS CO., LTD., Suwon-si (KR)

(72) Inventors: Ilju MUN, Suwon-si (KR); Keon KUK, Suwon-si (KR); Joseph AHN, Suwon-si (KR)

(73) Assignee: SAMSUNG ELECTRONICS CO., LTD., Suwon-si (KR)

(21) Appl. No.: 19/182,265

(22) Filed: Apr. 17, 2025

Related U.S. Application Data
(63) Continuation of application No. PCT/KR2025/003780, filed on Mar. 25, 2025.

(30) Foreign Application Priority Data
May 21, 2024 (KR) 10-2024-0065899
Jul. 2, 2024 (KR) 10-2024-0087136

(51) Int. Cl. H05K 1/02

(52) U.S. Cl. CPC H05K 1/023

(57) ABSTRACT

A multi-layered printed circuit board assembly, includes a first substrate; a second substrate above the first substrate; a plurality of connection structures between the first substrate and the second substrate, the plurality of connection structures being configured to connect the first substrate and the second substrate; and a shielding structure connected to a first ground portion of the first substrate and a second ground portion of the second substrate, wherein the shielding structure is configured to form a closed area to shield electromagnetic interference of an electronic component in the closed area.

### CROSS-REFERENCE TO RELATED APPLICATIONS

This application is a by-pass continuation application of International Application No. PCT/KR2025/003780 designating the United States, filed on Mar. 25, 2025, in the Korean Intellectual Property Receiving Office, which claims priority from Korean Patent Application Nos. 10-2024-0065899, filed on May 21, 2024, and 10-2024-0087136, filed on Jul. 2, 2024, in the Korean Intellectual Property Office, the disclosures of which are hereby incorporated by reference herein in their entireties.

### BACKGROUND

### 1. Field

The disclosure relates to a multi-layered printed circuit board assembly and an electronic device including the same multi-layered printed circuit.

### 2. Description of Related Art

Electronic devices, such as smartphones and tablet computers, are important for rapidly changing information transfer. These electronic devices facilitate users' tasks through a graphical user interface (GUI) environment using a touch screen and provide various multimedia based on a web environment.

The electronic devices are equipped with various communication components and electronic components to provide various functions. For example, the electronic devices provide a music playback function by having speakers. Further, the electronic devices have a camera to provide a photographing function. Also, the electronic devices provide a communication function to communicate with other electronic devices through a network by a communication module equipped therein.

To achieve higher-performance electronic devices, a plurality of electronic components are mounted in a limited printed circuit board space.

The above-described information may be provided as related art for the purpose of helping understanding of the disclosure. The foregoing cannot be claimed as, or used to determine, the prior art related to the disclosure.

### SUMMARY

According to an aspect of the disclosure, a multi-layered printed circuit board assembly, includes: a first substrate: a second substrate above the first substrate; a plurality of connection structures between the first substrate and the second substrate, the plurality of connection structures being configured to connect the first substrate and the second substrate: and a shielding structure connected to a first ground portion of the first substrate and a second ground portion of the second substrate, wherein the shielding structure is configured to form a closed area to shield electromagnetic interference of an electronic component in the closed area.

According to an aspect of the disclosure, an electronic device includes: a housing: a first substrate in the housing: a second substrate in the housing, the second substrate being above the first substrate: a plurality of connection structures between the first substrate and the second substrate, the plurality of connection structures being configured to connect the first substrate and the second substrate; and a shielding structure connected to a first ground portion of the first substrate and a second ground portion of the second substrate, wherein the shielding structure is configured to form a closed area to shield electromagnetic interference of an electronic component in the closed area.

Effects achievable in example embodiments of the disclosure are not limited to the above-mentioned effects, but other effects not mentioned may be apparently derived and understood by one of ordinary skill in the art to which example embodiments of the disclosure pertain, from the following description. In other words, unintended effects in practicing embodiments of the disclosure may also be derived by one of ordinary skill in the art from example embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an electronic device in a network environment according to one or more embodiments;

FIG. 2A illustrates a front perspective view of an electronic device according to an embodiment;

FIG. 2B illustrates a rear perspective view of the electronic device of FIG. 2A;

FIG. 3 illustrates an exploded perspective view of an electronic device according to an embodiment;

FIG. 4 illustrates an exploded perspective view of a multi-layered printed circuit board according to an embodiment;

FIG. 5 illustrates a cross-sectional view of a multi-layered printed circuit board according to an embodiment;

FIG. 6 illustrates an additional mounting area of a multi-layered printed circuit board according to an embodiment;

FIGS. 7A and 7B illustrate a method for printing a shielding structure of a multi-layered printed circuit board according to an embodiment;

FIGS. 8A and 8B illustrate a portion of a process of manufacturing a multi-layered printed circuit board according to an embodiment;

FIGS. 9A and 9B illustrate a portion of a process of manufacturing a multi-layered printed circuit board according to an embodiment;

FIGS. 10A and 10B illustrate a portion of a process of manufacturing a multi-layered printed circuit board according to an embodiment;

FIGS. 11A and 11B illustrate a portion of a process of manufacturing a multi-layered printed circuit board according to an embodiment;

FIG. 12 illustrates an exploded perspective view of a multi-layered printed circuit board assembly according to an embodiment;

FIGS. 13 to 15 illustrate examples of cross-sectional views of a multi-layered printed circuit board assembly according to one or more embodiments;

FIG. 16 illustrates an example nozzle used to form a shielding structure as shown in FIGS. 13 to 15;

FIGS. 17A and 17B illustrate examples of cross-sectional views of a printed circuit board according to an embodiment;

FIG. 18 illustrates a state in which a filling material fills an inside of a printed circuit board assembly according to an embodiment; and

FIGS. 19A to 19D illustrate a shielding structure applied to a multi-layered printed circuit board assembly having a multi-layer structure of three of more layers according to one or more embodiments.

Reference may be made to the accompanying drawings in the following description, and specific examples that may be practiced are shown as examples within the drawings. Other examples may be utilized and structural changes may be made without departing from the scope of the various examples.

### DETAILED DESCRIPTION

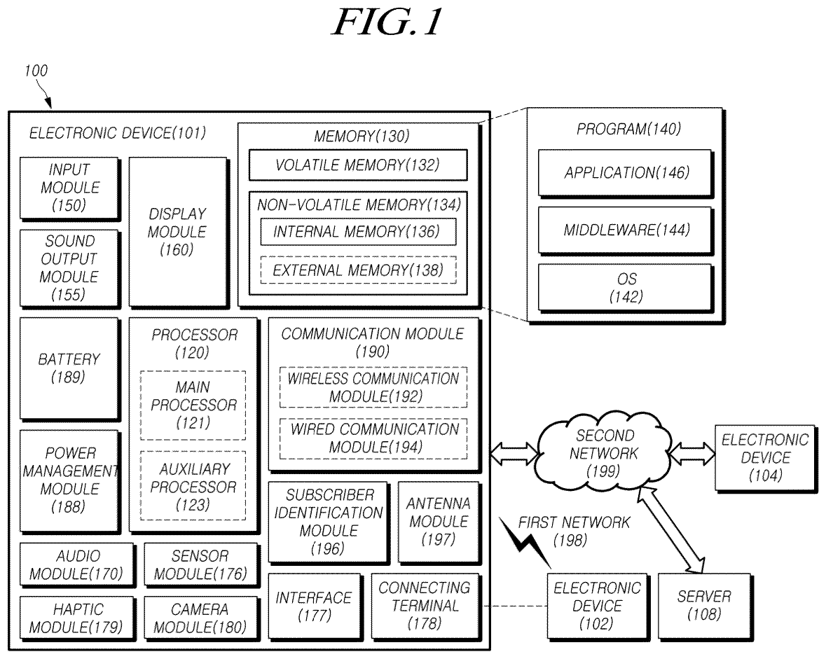

One or more embodiments of the disclosure are merely exemplified herein with reference to FIGS. 1 to 19D, to describe the principle of the disclosure, and should not be interpreted as limiting the scope of the disclosure. Those skilled in the art will understand that the principle of the disclosure may be implemented in any appropriately disposed system or device.

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

FIG. 1 illustrates an electronic device in a network environment according to one or more embodiments.

In FIG. 1, the electronic device 101 in the network environment 100 may communicate with at least one of an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more these artificial neural networks. But the disclosure is not limited to above examples of the artificial neural networks. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., via a wire) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., via a wire) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of Ims or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to one or more embodiments, the antenna module 197 may form a mmWave antenna module. According to an embodiment, the mmWave antenna module may include a PCB, a RFIC disposed on a first side (e.g., the bottom surface) of the PCB, or adjacent to the first side and capable of supporting a designated high-frequency band (e.g., the mmWave band), and a plurality of antennas (e.g., array antennas) disposed on a second side (e.g., the top or a side surface) of the PCB, or adjacent to the second side and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an Internet-of-things (IOT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

The electronic device according to one or more embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

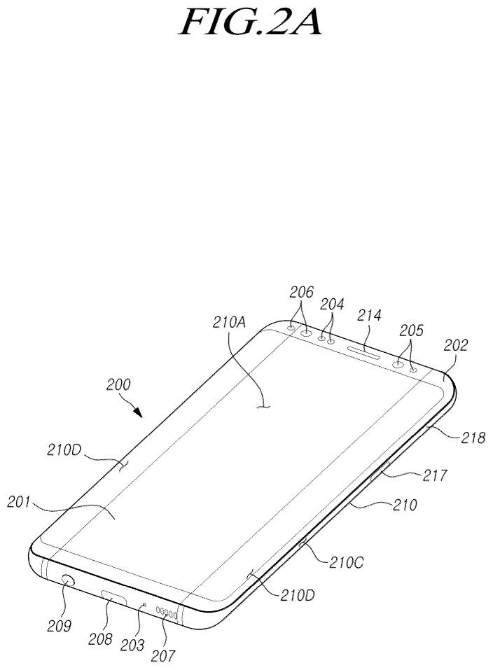

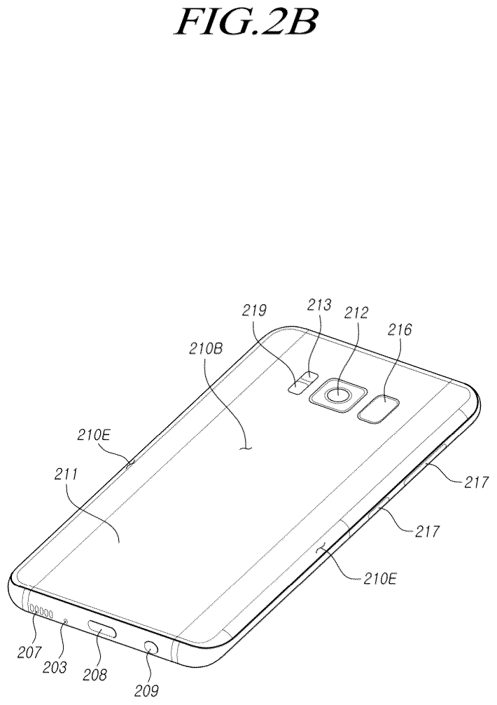

FIG. 2A illustrates a front perspective view of an electronic device according to an embodiment. FIG. 2B illustrates a rear perspective view of the electronic device of FIG. 2A.

In FIGS. 2A and 2B, according to an embodiment, an electronic device 200 may include a housing 210 including a first side (or front side or surface) 210A, a second side (or rear side or surface) 210B, and a third side (e.g., side or lateral surface) 210C surrounding a space between the first side 210A and the second side 210B. According to another embodiment, the housing may denote a structure forming part of the first side 210A, the second side 210B, and the third side 210C of FIG. 1. According to an embodiment, at least part of the first side 210A may have a substantially transparent front plate 202 (e.g., a glass plate or polymer plate including various coat layers). The second side 210B may be formed by a rear plate 211 that is substantially opaque. For example the rear plate 211 may be formed of laminated or colored glass, ceramic, polymer, metal (e.g., aluminum, stainless steel (STS), or magnesium), or a combination of at least two of these materials. The third side 210C may be formed by a side bezel structure (or a “side member”) 218 that couples to the front plate 202 and the rear plate 211 and includes a metal and/or polymer. According to an embodiment, the rear plate 211 and the side bezel plate 218 may be integrally formed together and include the same material (e.g., a metal, such as aluminum).

In the embodiment illustrated, the front plate 202 may include two first regions 210D, curved (or bent), seamlessly extend from the first side 210A to the rear plate 211, on both the long (e.g., vertical) edges of the front plate 202. In the embodiment (refer to FIG. 2) illustrated, the rear plate 211 may include second regions 210E, curved (or bent), seamlessly extend from the second side 210B to the front plate 202, on both the long edges. According to an embodiment, the front plate 202 (or the rear plate 211) may include at least one of the first regions 210D (or the second regions 210E). In one embodiment, the first regions 210D or the second regions 210E may partially be excluded. According to an embodiment, at side view of the electronic device 200, the side bezel structure 218 may have a first thickness (or width) of sides that do not have the first regions 210D or the second regions 210E and a second thickness, which is smaller than the first thickness, of sides that have the first regions 210D or the second regions 210E. In an embodiment, the first regions 210D or second regions 210E may be formed to be flat, together the first side 210A or second side 210B, to form substantially one flat surface without bending (e.g., curved).

According to an embodiment, the electronic device 200 may include at least one or more of a display 201, audio modules 203, 207, and 214, sensor modules 204, 216, and 219, camera modules 205, 212, and 213, key input devices 217, a light emitting device 206, and connector holes 208 and 209. According to an embodiment, the electronic device 200 may exclude at least one (e.g., the key input device 217 or the light emitting device 206) of the components or may add other components.

The display 201 may be exposed (e.g., displayed) through a significant portion of the front plate 202. According to an embodiment, at least a portion of the display 201 may be exposed through the front plate 202 forming the first side 210A and the first regions 210D of the third side 210C. According to an embodiment, the edge of the display 201 may be formed to be substantially the same in shape as an adjacent outer edge of the front plate 202. According to another embodiment, the interval (e.g., space) between the outer edge of the display 201 and the outer edge of the front plate 202 may remain substantially even to give a larger area of exposure to the display 201.

According to an embodiment, the screen display area of the display 201 may have a recess or opening in a portion of the screen display area. At least one or more of the audio module 214, sensor module 204, camera module 205, and light emitting device 206 may be aligned with the recess or opening. According to another embodiment, at least one or more of the audio module 214, sensor module 204, camera module 205, fingerprint sensor 216, and light emitting device 206 may be included on the rear side of the screen display area of the display 201. According to an embodiment, the display 201 may be coupled with, or adjacent, a touch detecting circuit, a pressure sensor capable of measuring the strength (pressure) of touches, and/or a digitizer for detecting a magnetic field-type stylus pen. According to an embodiment, at least part of the sensor modules 204 and 219 and/or at least part of the key input devices 217 may be disposed in the first regions 210D and/or the second regions 210E.

The audio modules 203, 207, and 214 may include a microphone hole 203 and speaker holes 207 and 214. The microphone hole 203 may have a microphone inside to obtain external sounds. According to an embodiment, there may be a plurality of microphones to be able to detect (e.g., identify) the direction of a sound. The speaker holes 207 and 214 may include an external speaker hole 207 and a phone receiver hole 214. According to an embodiment, the speaker holes 207 and 214 and the microphone hole 203 may be implemented as a single hole, or speakers may be rested without the speaker holes 207 and 214 (e.g., piezo speakers).

The sensor modules 204, 216, and 219 may generate an electrical signal or data value corresponding to an internal operating state or external environmental state of the electronic device 200. For example, the sensor modules 204, 216, and 219 may include a first sensor module 204 (e.g., a proximity sensor) and/or a second sensor module (e.g., a fingerprint sensor), which is disposed on the first side 210A of the housing 210, and/or a third sensor module 219 (e.g., a heartrate monitor (HRM) sensor) and/or a fourth sensor module 216 (e.g., a fingerprint sensor) disposed on the second side 210B of the housing 210. The fingerprint sensor may be disposed on the second side 210B as well as on the first side 210A (e.g., the display 201) of the housing 210. The electronic device 200 may further include sensor modules, e.g., at least one of a gesture sensor, a gyro sensor, an atmospheric pressure sensor, a magnetic sensor, an acceleration sensor, a grip sensor, a color sensor, an IR sensor, a biometric sensor, a temperature sensor, a humidity sensor, or an illuminance sensor 204.

The camera modules 205, 212, and 213 may include a first camera device 205 disposed on the first side 210A of the electronic device 200, a second camera device 212, or a flash 213 disposed on the second side 210B. The camera devices 205 and 212 may include one or more lenses, an image sensor, and/or an image signal processor. For example, the flash 213 may include a light emitting diode (LED) or a xenon lamp. According to an embodiment, two or more lenses (an IR camera, a wide-angle lens, and a telephoto lens) and image sensors may be disposed on one surface of the electronic device 200.

The key input device 217 may be disposed on the third side 210C of the housing 210. According to another embodiment, the electronic device 200 may exclude all or some of the above-mentioned key input devices 217 and the excluded key input devices 217 may be implemented in other forms as soft keys, on the display 201. According to an embodiment, the key input device may include the sensor module 216 disposed on the second side 210B of the housing 210.

For example, the light emitting device 206 may be disposed on the first side 210A of the housing 210. For example, the light emitting device 206 may provide information about the state of the electronic device 200 in the form of light. According to an embodiment, the light emitting device 206 may provide a light source that interacts with the camera module 205. For example, the light emitting device 206 may include a LED, an IR LED, or a xenon lamp.

The connector holes 208 and 209 may include a first connector hole 208 for receiving a connector (e.g., a USB connector) for transmitting or receiving power and/or data to/from an external electronic device and/or a second connector hole 209 (e.g., an earphone jack) for receiving a connector for transmitting or receiving audio signals to/from the external electronic device.

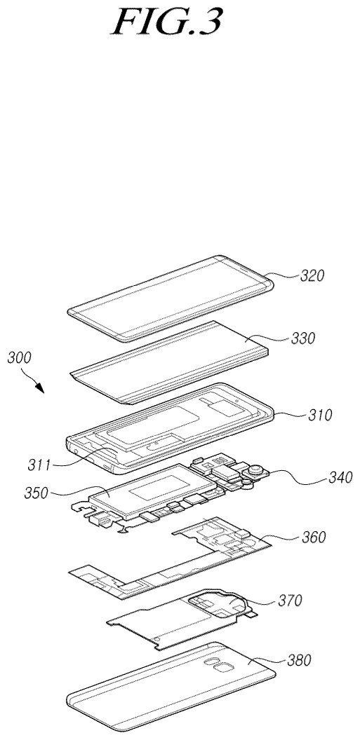

FIG. 3 illustrates an exploded perspective view of an electronic device according to an embodiment:

In FIG. 3, an electronic device 300 may include a side bezel structure 310, a first supporting member 311 (e.g., a bracket), a front plate 320, a display 330, a PCB 340, a battery 350, a second supporting member 360 (e.g., a rear case), an antenna 370, and a rear plate 380. According to an embodiment, the electronic device 300 may exclude at least one (e.g., the first supporting member 311 or the second supporting member 360) of the components or may add other components. At least one of the components of the electronic device 300 may be the same or similar to at least one of the components of the electronic device 100 of FIG. 1 or 2 and no duplicate description is made below.

The first supporting member 311 may be disposed inside the electronic device 300 to be connected with the side bezel structure 310 or integrated with the side bezel structure 310. For example, the first supporting member 311 may be formed of a metal and/or non-metallic material (e.g., polymer). The display 330 may be joined onto one surface of the first supporting member 311, and the PCB 340 may be joined onto the opposite surface of the first supporting member 311. A processor, memory, and/or interface may be mounted on the PCB 340. For example, the processor may include one or more of a central processing unit, an application processor, a graphic processing device, an image signal processing, a sensor hub processor, or a communication processor.

For example, the memory may include a volatile or non-volatile memory.

For example, the interface may include a HDMI, and a USB interface, a SD card interface, and/or an audio interface. For example, the interface may electrically or physically connect the electronic device 300 with an external electronic device and may include a USB connector, an SD card/multimedia card (MMC) connector, or an audio connector.

The battery 350 may be a device for supplying power to at least one component of the electronic device 300. For example, the battery 189 may include a primary cell which is not rechargeable, a secondary cell which is rechargeable, or a fuel cell. At least a portion of the battery 350 may be disposed on substantially the same plane as the PCB 340. The battery 350 may be integrally or detachably disposed inside the electronic device 300.

The antenna 370 may be disposed between the rear plate 380 and the battery 350. For example, the antenna 370 may include a near-field communication (NFC) antenna, a wireless charging antenna, and/or a magnetic secure transmission (MST) antenna. For example, the antenna 370 may perform short-range communication with an external device or may wirelessly transmit or receive power necessary for charging. According to an embodiment, an antenna structure may be formed by a portion or combination of the side bezel structure 310 and/or the first supporting member 311.

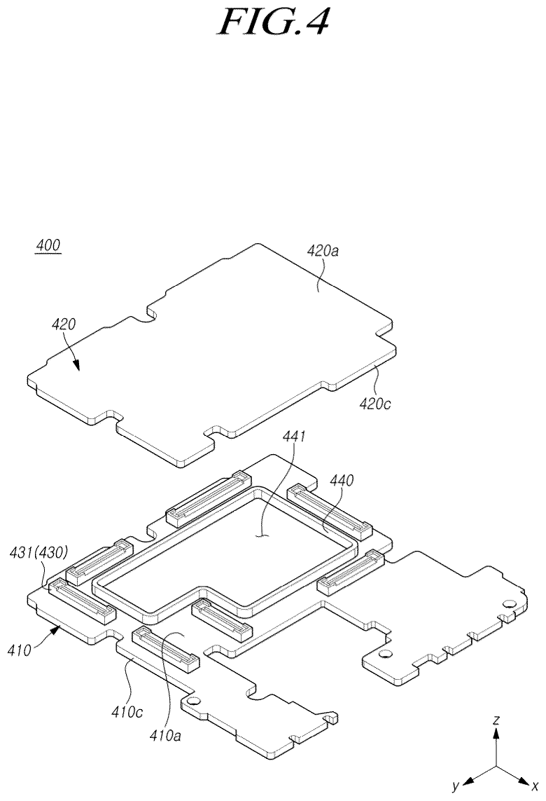

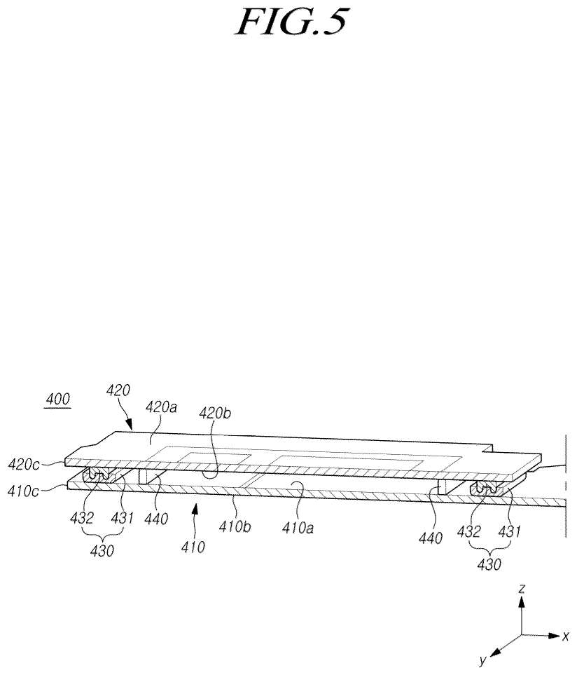

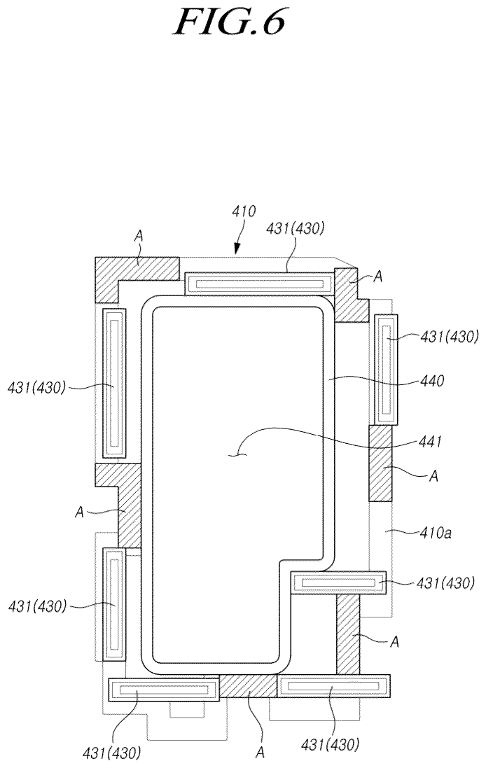

FIG. 4 illustrates an exploded perspective view of a multi-layered printed circuit board according to an embodiment. FIG. 5 illustrates a cross-sectional view of a multi-layered printed circuit board according to an embodiment. FIG. 6 illustrates an additional mounting area of a multi-layered printed circuit board according to an embodiment.

In one or more embodiments, electronic components may be mounted on the substrates illustrated in FIGS. 4 to 6. The multi-layered PCB assembly 400 illustrated in FIGS. 4 to 6 may be included in various kinds of electronic devices. For example, the multi-layered PCB assembly 400 may be included in the electronic device (200) shown in FIGS. 2A to 3 but is not limited thereto.

The multi-layered PCB assembly 400 illustrated in FIGS. 4 to 6 may be substantially the same as the PCB of FIG. 3 (e.g., the PCB 340 of FIG. 3).

The shape of the multi-layered PCB assembly 400 illustrated in FIGS. 4 to 6 is an example structure, and the scope of the disclosure is not limited by the structure illustrated.

In FIGS. 4 to 6, the multi-layered PCB assembly 400 may include a first substrate 410, a second substrate 420, a connection structure 430, a shielding structure 440, and an electronic element. The first substrate 410 and the second substrate 420 may be disposed to vertically overlap each other. The first substrate 410 and the second substrate 420 may be vertically spaced apart from each other. The multi-layered PCB assembly 400 may be disposed within a housing of an electronic device (e.g., the housing 210 of FIG. 2A) (e.g., the electronic device 200 of FIG. 2A). Hereinafter, a structure in which two substrates are stacked is described as an example, but the scope of the disclosure may also be applied to a structure in which three or more substrates are stacked.

According to an embodiment, a processor, a memory, and/or an interface may be mounted on the first substrate 410 and the second substrate 420. For example, the processor may include one or more of a central processing unit, an application processor, a graphic processing device, an image signal processing, a sensor hub processor, or a communication processor. For example, the memory may include a volatile or non-volatile memory. interface, and/or an audio interface. For example, the interface may electrically or physically connect the electronic device 300 with an external electronic device and may include a USB connector, an SD card/MMC connector, or an audio connector.

According to an embodiment, various types of substrates (e.g., ceramic substrates, PCBs, and flexible substrates) well known in the art may be used as the first substrate 410 and the second substrate 420. In one or more embodiments, electrically connected wiring patterns may be formed on surfaces of the first substrate 410 and the second substrate 420.

According to an embodiment, each of the first substrate 410 and the second substrate 420 may be divided into a single-layer PCB in which wiring is formed on at least one side and a double-layer PCB in which circuit wiring is formed on two opposite sides. In the case of the substrate for a double-layer PCB, upper and lower circuit wirings may be electrically connected to each other through a conductive structure penetrating the body.

According to an embodiment, the first substrate 410 may include an upper side 410a and a lower side 410b. According to an embodiment, the second substrate 420 may include an upper side 420a and a lower side 420b. The upper side 410a of the first substrate 410 and the lower side 420b of the second substrate 420 may be disposed to face each other. For example, the electronic device may be mounted on the upper side 410a or the lower side 410b of the first substrate 410. For example, the electronic device may be mounted on the upper side 420a or the lower side 420b of the second substrate 420.

According to an embodiment, some of a plurality of electronic elements may be disposed in a closed area formed by the shielding structure 440.

According to an embodiment, the connection structure 430 may include all structures which may be assembled and separated. For example, the connection structure 430 may include a connector. For example, the connection structure 430 may include a header and various types of connectors such as socket connectors, board-to-board connectors, mezzanine connectors, or flexible connectors. A plurality of connection structures 430 may be disposed.

According to an embodiment, the connection structure 430 may include a first connection portion 431 and a second connection portion 432. The first connection portion 431 may be disposed or mounted on the first substrate 410. For example, the first connection portion 431 may be disposed or mounted on the upper side 410a of the first substrate 410. The second connection portion 432 may be disposed or mounted on the second substrate 420. For example, the second connection portion 432 may be disposed or mounted on the lower side 420b of the second substrate 420. The first connection portion 431 and the second connection portion 432 may be detachably coupled to each other. The first connection portion 431 and the second connection portion 432 may be disposed at positions vertically overlapping each other.

According to an embodiment, the shielding structure 440 may include a conductive material (or an electrically conductive filler). For example, the shielding structure 440 may include metals such as Ag, Cu, Ag coated Cu, Ni, Al, and Sn. For example, the shielding structure 440 may include conductive carbon such as carbon black, carbon nanotubes (CNT), and graphite. For example, the shielding structure 440 may include at least one conductive polymer material of polypyrrole or polyaniline.

According to an embodiment, the shielding structure 440 may include a binder resin. For example, the shielding structure 440 may include a silicone resin, an epoxy resin, a urethane resin, an alkyd resin, or the like.

According to an embodiment, the shielding structure 440 may further include an additive and a solvent for enhancing performance. For example, the shielding structure 440 may include at least one of a thickening agent, an antioxidant, or a polymer surfactant as an additive. For example, the shielding structure 440 may include at least one of water or alcohol as an additive.

According to an embodiment, the shielding structure 440 may have thixotropy, which is a property in which fluidity increases when a shear force is applied and maintains its shape when the shear force is removed.

For example, the width of the shielding structure 440 may be 200 to 700 micrometers. For example, the height of the shielding structure 440 may be 100 to 1300 micrometers. However, without limitations thereto, the shielding structure 440 may be applied in various widths and heights according to the area and mounting integration of the substrate.

According to an embodiment, the shielding structure 440 may be disposed to contact the ground portion of the first substrate 410 and the ground portion of the second substrate 420. The shielding structure 440 may be electrically coupled to the ground portion. According to an embodiment, the closed area 441 may be partitioned by the shielding structure 440. For example, the closed area 441 may be defined by the ground portion of the first substrate 410 or the ground portion of the second substrate 420. For example, the shielding structure 440 may be printed or applied along the ground portion of the first substrate 410 or the ground portion of the second substrate 420 defining the closed area. Here, the closed area 441 may be referred to as a shielding area. Here, the ground part may be referred to as a ground pad.

According to an embodiment, the shielding structure 440 may shield electromagnetic interference (spurious waves or noise) generated from an electronic element mounted in the closed area 441.

According to an embodiment, the shielding structure 440 may be referred to as a shielding wall or a shielding dam that forms the closed area 441.

According to an embodiment, if the shielding structure 440, as in the disclosure, is used, it may be flexibly applied to the deformed closed area 441 even when the closed area 441 (or the shielding area) is re-designated due to a design change of the product.

According to an embodiment, if the shielding structure 440, as in the disclosure, is used, the repair process of a product such as debugging may be more easily performed. If some defects occur during the manufacturing process, a process of separating and reassembling the first substrate 410 and the second substrate 420 may be required. The multi-layered PCB assembly 400 of the disclosure may be easily separated because the first substrate 410 and the second substrate 420 are coupled by the connection structure 430 and may be coupled after printing the shielding structure 440 again after separation, thereby more easily performing debugging. In the case of a conventional multi-layered PCB assembly using an interposer, heat application is required to melt solder balls for separation, and in the process, solder balls coupled to the surrounding electronic elements also melt together. In the disclosure, the first substrate 410 and the second substrate 420 may be easily separated and repaired without such problems.

According to an embodiment, since the shielding structure 440 as in the disclosure is not soldered, the defect rate may be reduced during a manufacturing process. If a shield can or interposer is disposed to form a shielding structure, an additional soldering process is required to bond the shield can or interposer to the substrate. As the soldering process is added, manufacturing defects due to soldering defects may occur. Since the shielding structure 440 of the disclosure does not require a separate soldering process, the defect rate may be reduced during a manufacturing process.

In FIG. 6, if the connection structure 430 is used compared to the interposer forming a closed area, an additional mounting area A may be secured as shown. As electronic devices are downsized (e.g., made smaller) and the mounting density of electronic elements mounted on a substrate increases, it is important to secure an additional mounting area A in a limited space. The additional mounting area A may be an area to be occupied by the interposer when the interposer is used instead of the connection structure 430. The multi-layered PCB assembly 400 of the disclosure may secure an additional mounting area by shielding electromagnetic interference of electronic elements with a small area through the shielding structure 440 and using a connection structure rather than an interposer.

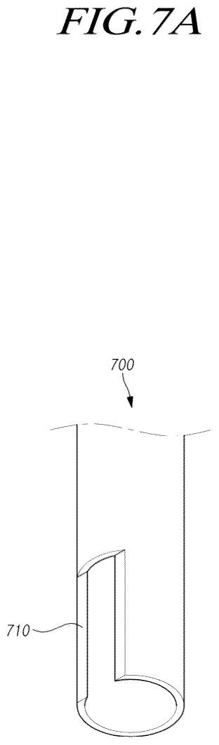

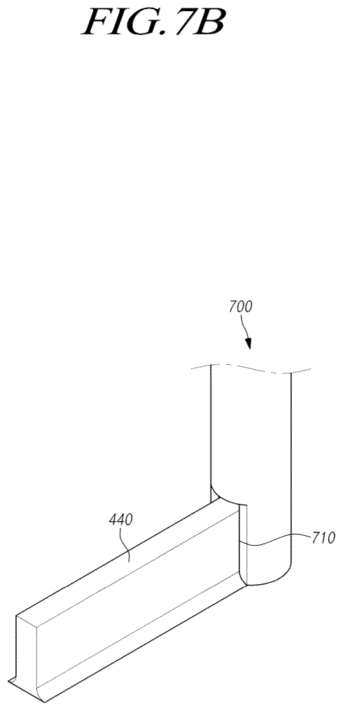

FIGS. 7A and 7B illustrate a method for printing a shielding structure of a multi-layered printed circuit board according to an embodiment.

According to an embodiment, the shielding structure (e.g., the shielding structure 440 of FIG. 4) illustrated in FIGS. 4 and 5 may be printed by a first nozzle 700 illustrated in FIGS. 7A and 7B. The first nozzle 700 may be referred to as a side slot nozzle.

According to an embodiment, the first nozzle 700 may include a side slot 710 formed to discharge the shielding structure 440. The shielding structure 440 may be discharged through the side slot 710 of the first nozzle 700.

According to an embodiment, the shielding structure 440 may have thixotropy. As the shear force is applied to the first nozzle 700, the fluidity of the shielding structure 440 increases, and it may be discharged through the side slot 710. After the shielding structure 440 is discharged, the shear force is removed to maintain the shape after the discharge.

According to an embodiment, the first nozzle 700 may be configured to be rotatable while moving in a horizontal direction. When the shielding structure 440 is printed using the first nozzle 700, the shielding structure 440 may be printed by one time of printing without stacking several times, thereby shortening the manufacturing time. However, without limitations thereto, the shielding structure 440 may be stacked multiple times and processed.

If the shielding structure 440 is printed on the substrate in a manner using the first nozzle 700, a closed area may be formed with the shielding structure 440 having a narrow width. Further, the area occupied by the shielding structure 440 on the substrate is small, which may be advantageous for increasing the mounting density of electronic elements.

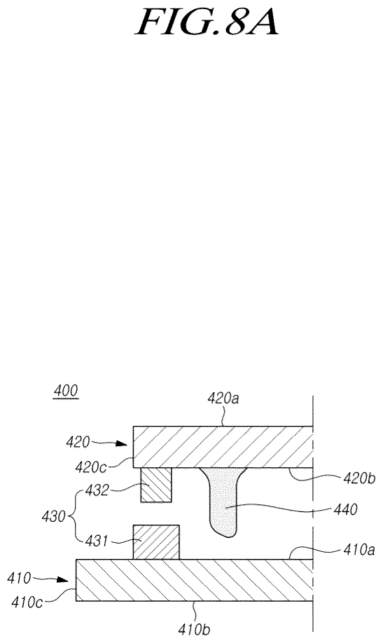

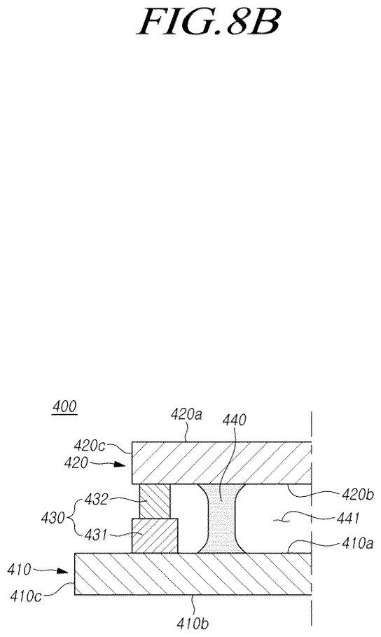

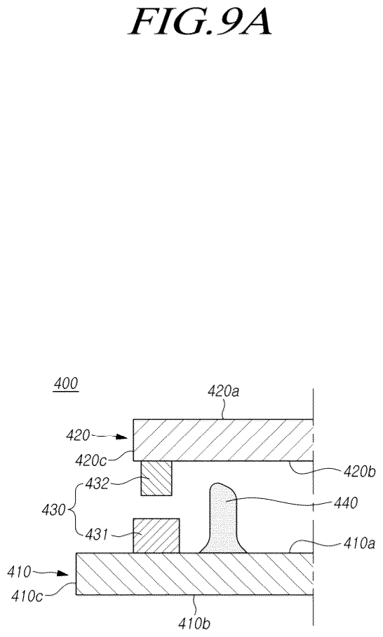

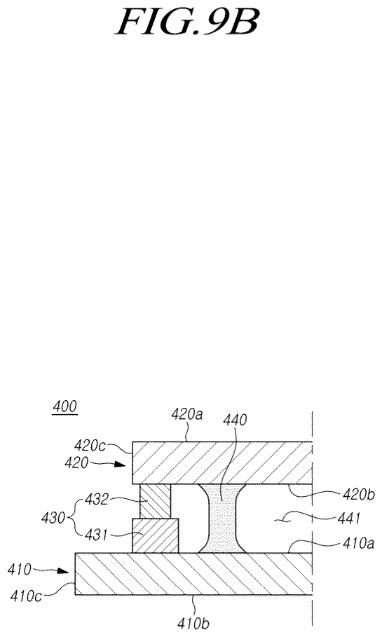

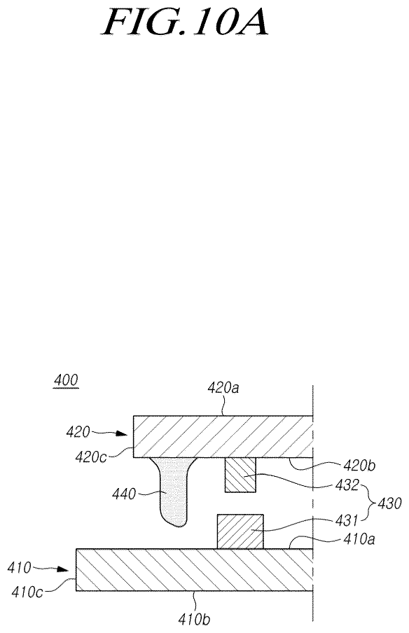

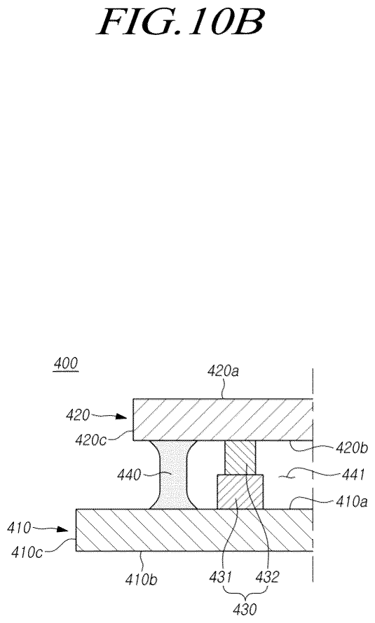

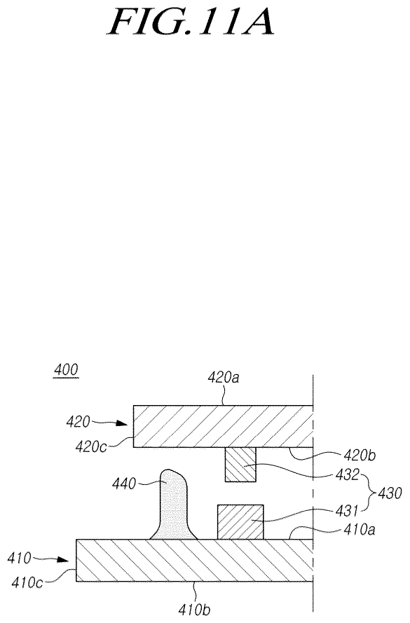

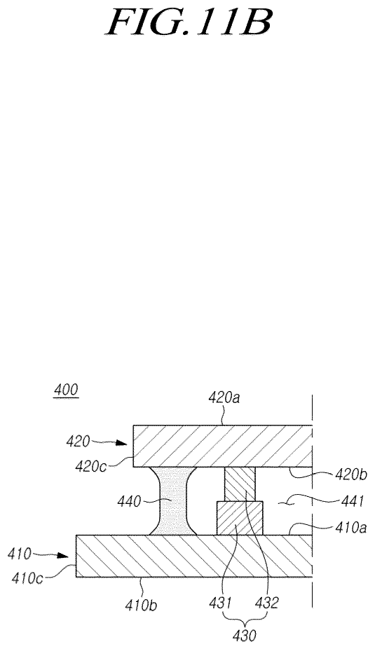

FIGS. 8A and 8B illustrate a portion of a process of manufacturing a multi-layered printed circuit board according to an embodiment. FIGS. 9A and 9B illustrate a portion of a process of manufacturing a multi-layered printed circuit board according to an embodiment. FIGS. 10A and 10B illustrate a portion of a process of manufacturing a multi-layered printed circuit board according to an embodiment. FIGS. 11A and 11B illustrate a portion of a process of manufacturing a multi-layered printed circuit board according to an embodiment.

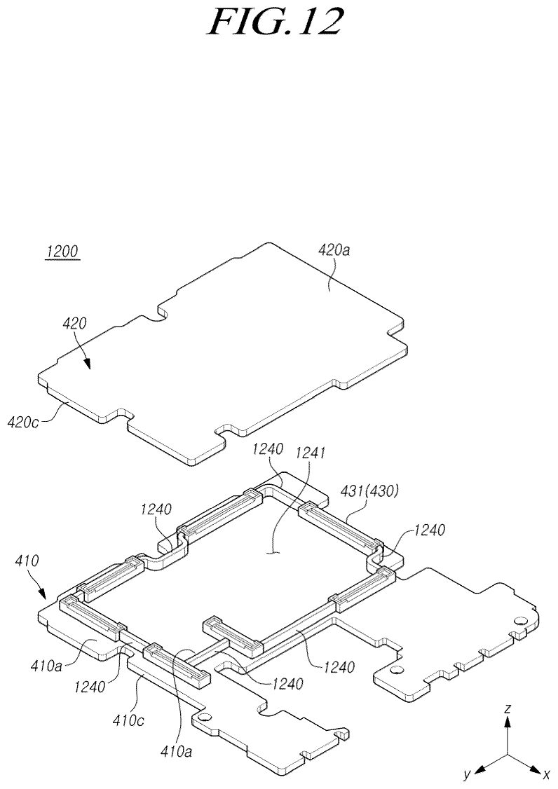

The structure of the multi-layered PCB assembly 400 illustrated in FIGS. 8A to 11B may be included in the electronic device of FIGS. 2A to 3 (e.g., the electronic device 200 of FIG. 2A). The embodiments illustrated in FIGS. 8A to 11B each may be selectively combined with the embodiments of FIGS. 4 to 7. The embodiments shown in FIGS. 8A to 11B may be selectively combined with the embodiments of FIGS. 12 to 19D.

The embodiments of FIGS. 8A and 8B may be selectively combined with at least one of the embodiments of FIGS. 4 and 5, or the embodiments of FIGS. 9A to 11B.

The embodiments of FIGS. 9A and 9B may be selectively combined with at least one of the embodiments of FIGS. 4 and 5, the embodiments of FIGS. 8A and 8B, or the embodiments of FIGS. 10A to 11B.

The embodiments of FIGS. 10A and 10B may be selectively combined with at least one of the embodiments of FIGS. 4 and 5, the embodiments of FIGS. 8A to 9B, or the embodiments of FIGS. 11A and 11B.

The embodiments of FIGS. 11A and 11B may be selectively combined with at least one of the embodiments of FIGS. 4 and 5, or the embodiments of FIGS. 8A to 10B.

In FIGS. 8A to 11B, the placement position or coupling method of the shielding structure 440 included in the multi-layered PCB assembly 400 may vary according to one or more embodiments. The shapes illustrated in FIGS. 8A to 11B are exemplary, and the illustrated shapes do not limit the scope of the disclosure.

FIGS. 8A, 9A, 10A, and 11A illustrate a state before the first substrate 410 and the second substrate 420 are assembled. FIGS. 8B, 9B, 10B, and 11B illustrate a state in which the first substrate 410 and the second substrate 420 are assembled.

In the embodiments of FIGS. 8A and 8B and the embodiments of FIGS. 9A and 9B, the shielding structure 440 may be disposed or mounted inside the connection structure 430. The connection structure 430 may be disposed outside the shielding structure 440. The connection structure 430 may be disposed outside the closed area 441 to be formed by the shielding structure 440. The shielding structure 440 may be disposed farther from a lateral side 410c of the first substrate 410 or a lateral side 420c of the second substrate 420 than the connection structure 430.

As shown in FIGS. 8A and 8B, the shielding structure 440 may be printed on the second substrate 420 and then coupled to the first substrate 410.

As shown in FIGS. 9A and 9B, the shielding structure 440 may be printed on the first substrate 410 and then coupled to the second substrate 420.

In the embodiments of FIGS. 10A and 10B and the embodiments of FIGS. 11A and 11B, the shielding structure 440 may be disposed or mounted outside the connection structure 430. The connection structure 430 may be disposed inside the shielding structure 440. The connection structure 430 may be disposed inside the closed area 441 to be formed by the shielding structure 440. The shielding structure 440 may be disposed closer to the lateral side 410c of the first substrate 410 or the lateral side 420c of the second substrate 420 than the connection structure 430.

As shown in FIGS. 10A and 10B, the shielding structure 440 may be printed on the second substrate 420 and then coupled to the first substrate 410.

As shown in FIGS. 11A and 11B, the shielding structure 440 may be printed on the first substrate 410 and then coupled to the second substrate 420.

In one or more embodiments, the shielding structure 440 may be separately printed and then coupled to the first substrate 410 and the second substrate 420 during an assembly process.

FIG. 12 illustrates an exploded perspective view of a multi-layered printed circuit board assembly according to an embodiment.

The multi-layered PCB assembly 1200 of FIG. 12 may be included in the electronic device (e.g., the electronic device 200 of FIG. 2A) of FIGS. 2A to 3. The multi-layered PCB assembly 1200 of FIG. 12 may be substantially the same as the PCB of FIG. 3 (e.g., the PCB 340 of FIG. 3).

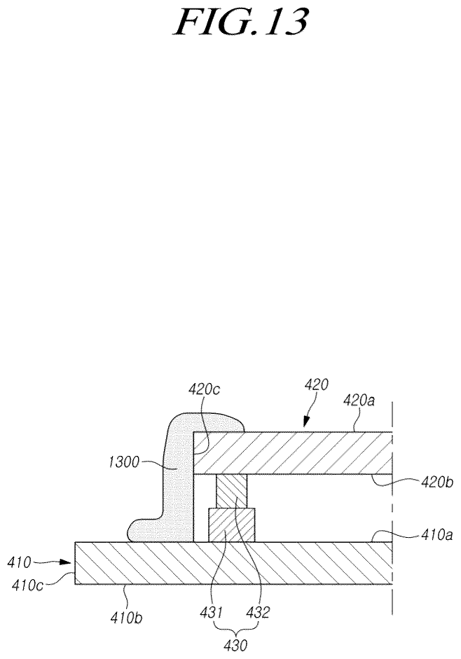

The embodiment of FIG. 12 may be selectively combined with the embodiment of FIGS. 4 to 11B. The embodiment of FIG. 12 may be selectively combined with the embodiments of FIGS. 13 to 19D.

Hereinafter, the same reference numerals are used to denote components substantially identical or similar to those described above.

In FIG. 12, the multi-layered PCB assembly 1200 may include a first substrate 410, a second substrate 420, a plurality of connection structures 430, and a shielding structure 1240.

According to an embodiment, the shielding structure 1240 may be disposed between the plurality of connection structures 430. The shielding structure 1240 may be disposed or printed to connect between two neighboring connection structures 430 among the plurality of connection structures 430. A plurality of shielding structures 1240 may be disposed between the plurality of connection structures 430.

According to an embodiment, the shielding structure 1240 may be disposed to contact, or be spaced a predetermined interval apart from, the connection structure 430 according to the type of the connection structure 430. Here, the predetermined interval may be an interval so small that electromagnetic interference generated by the electronic element mounted in the shielding area 1241 is not emitted to the outside.

According to an embodiment, the shielding area 1241 may refer to a space partitioned by the connection structure 430 and the shielding structure 1240.

As shown in FIG. 12, the shielding structure 1240 is disposed in the space between the connection structures 430, thereby increasing the mounting efficiency of electronic elements.

FIGS. 13 to 15 illustrate examples of cross-sectional views of a multi-layered printed circuit board assembly according to one or more embodiments.

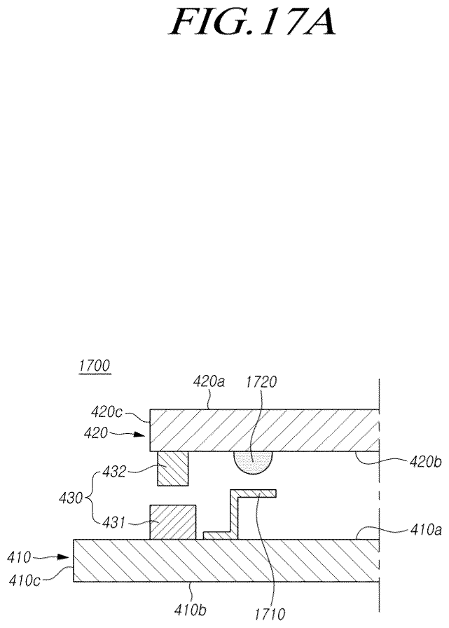

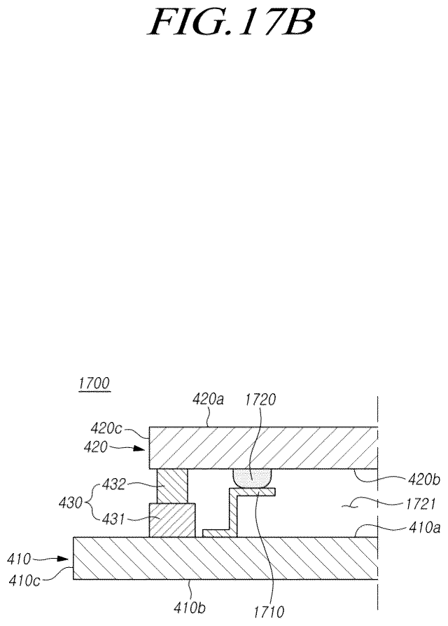

The embodiments of FIGS. 13 to 15 may be selectively combined with the embodiments of FIGS. 4 to 12. The embodiments of FIGS. 13 to 15 may be selectively combined with the embodiments of FIGS. 17A to 19D.

The embodiments shown in FIGS. 13 to 15 are example views for describing that a shielding structure may be configured with various structures.

In FIGS. 13 to 15, the shielding structure 1300, 1400, or 1500 may be disposed to contact at least one of a lateral side 410c of the first substrate 410 or a lateral side 420c of the second substrate 420. A ‘ground portion’ (or a ground pad) may be formed at or may correspond to a portion where the shielding structure 1300, 1400, or 1500 contacts each other (or contacts with the first substrate 410 and/or the second substrate 420). If a shielding structure is formed as shown in FIGS. 13 to 15, it may provide more advantages in securing a mounting area of an electronic element.

As shown in FIG. 13, if the sizes of the first substrate 410 and the second substrate 420 are different from each other, the shielding structure 1300 may be disposed or printed to contact at least one of the lateral sides 410c of the first substrate 410 or 420c of the second substrate 420. The shielding structure 1300 of FIG. 13 may be disposed to contact the upper side 410a of the first substrate 410 and the lateral side 420c of the second substrate 420. The shielding structure 1300 of FIG. 13 may be disposed to surround an edge portion of the second substrate 420.

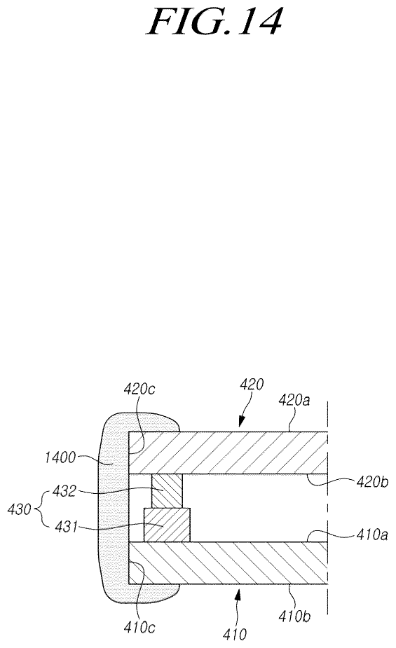

In FIG. 14, the shielding structure 1400 may be disposed to surround edge portions of the first substrate 410 and the second substrate 420. The shielding structure 1400 of FIG. 14 may be disposed to contact a portion of the lower side 410b and the lateral side 410c of the first substrate 410. The shielding structure 1400 of FIG. 14 may be disposed to contact a portion of the upper side 420a and the lateral side 420c of the second substrate 420.

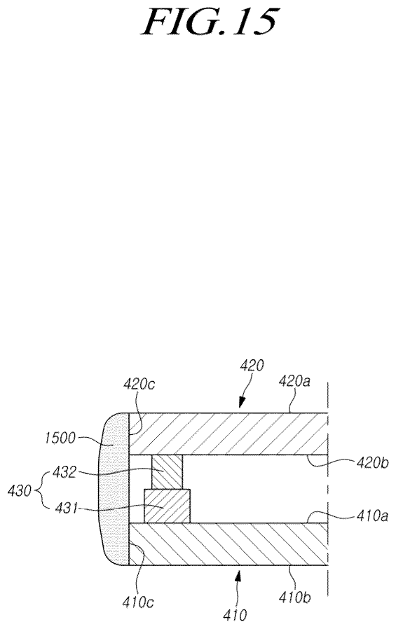

In FIG. 15, the shielding structure 1500 may be disposed to contact the lateral side 410c of the first substrate 410 and the lateral side 420c of the second substrate 420.

The shapes illustrated in FIGS. 13 to 15 are examples, and the disclosure is not limited to the illustrated shapes.

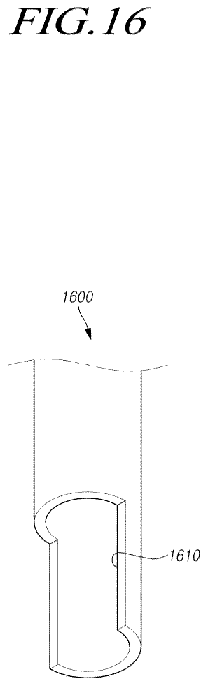

FIG. 16 illustrates an example nozzle used to form a shielding structure as shown in FIGS. 13 to 15.

According to an embodiment, the shielding structures 1300, 1400, or 1500 illustrated in FIGS. 13 to 15 may be printed by the second nozzle 1600 illustrated in FIG. 16. The second nozzle 1600 may be referred to as a half-slot nozzle.

According to an embodiment, the second nozzle 1600 may include a half slot 1610 formed to discharge the shielding structure 1300, 1400, or 1500. The shielding structure 1300, 1400, or 1500 may be discharged through the half slot 1610 of the second nozzle 1600.

According to an embodiment, the shielding structure 1300, 1400, or 1500 may have thixotropy. As a shear force is applied to the second nozzle 1600, the fluidity of the shielding structures 1300, 1400, or 1500 may increase and it may be discharged through the half slot 1610. After the shielding structure 1300, 1400, or 1500 is discharged, the shear force is removed, and the shape after the discharging may be maintained.

FIGS. 17A and 17B illustrate examples of cross-sectional views of a printed circuit board according to an embodiment.

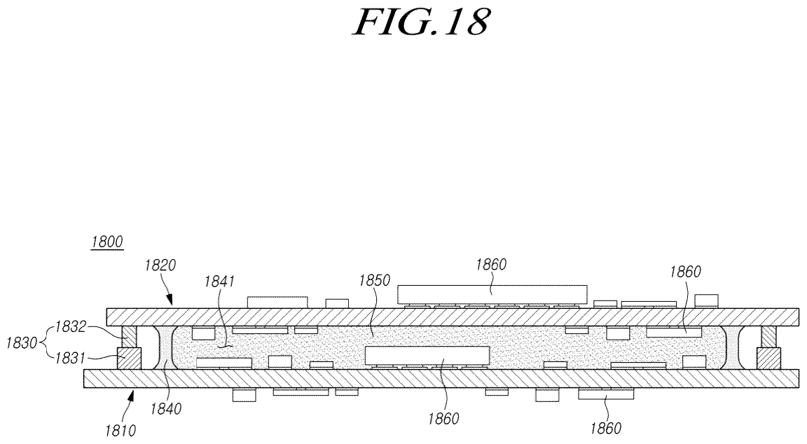

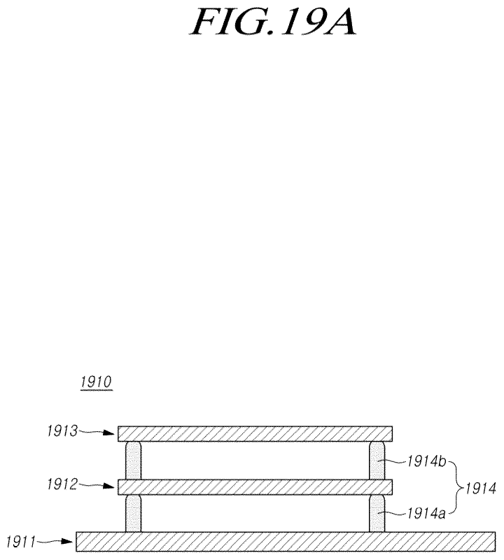

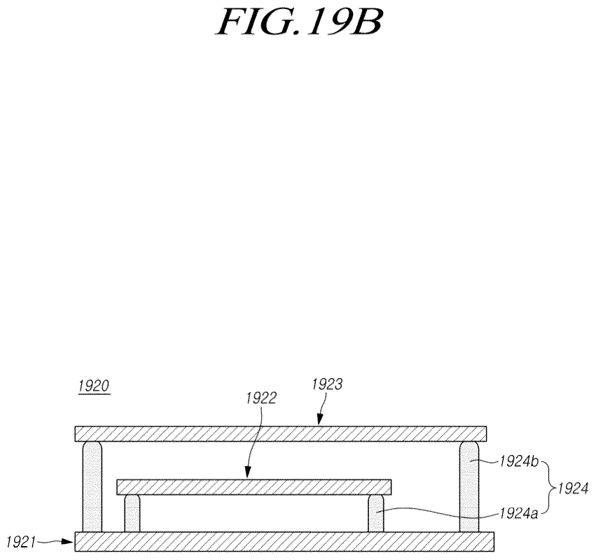

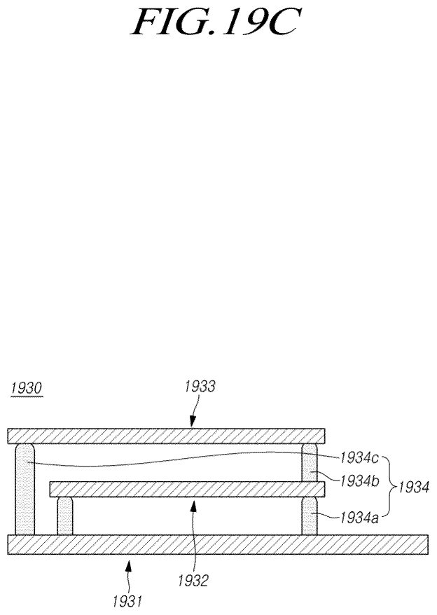

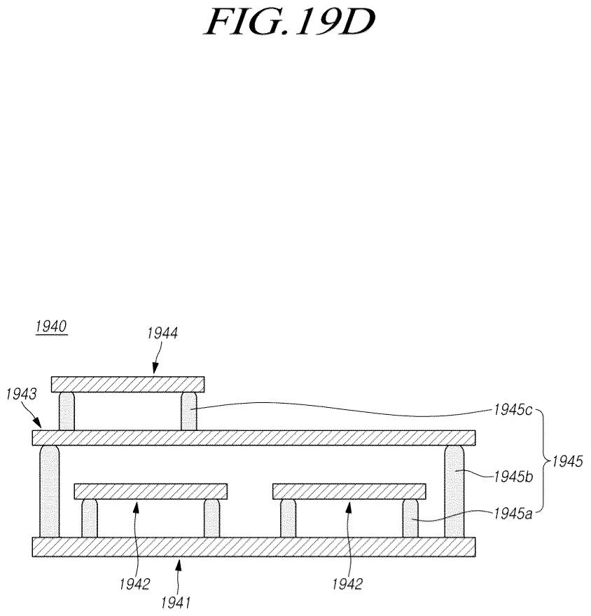

The embodiments of FIGS. 17A and 17B may be selectively combined with the embodiments of FIGS. 4 to 16. The embodiments of FIGS. 17A and 17B may be selectively combined with the embodiments of FIGS. 18 to 19D.

The multi-layered PCB assembly 1700 of FIGS. 17A and 17B may be included in the electronic devices of FIGS. 2A to 3 (e.g., the electronic device 200 of FIG. 2A). The multi-layered PCB assembly 1700 of FIGS. 17A and 17B may be substantially the same as the PCB of FIG. 3 (e.g., the PCB 340 of FIG. 3).

Hereinafter, the same reference numerals are used to denote components substantially identical or similar to those described above.

In FIGS. 17A and 17B, the multi-layered PCB assembly 1700 may include a first substrate 410, a second substrate 420, a connection structure 430, a first shielding structure 1710, and a second shielding structure 1720. FIG. 17A illustrates a state before the first substrate 410 and the second substrate 420 are assembled. FIG. 17B illustrates a state in which the first substrate 410 and the second substrate 420 are assembled.

The first shielding structure 1710 may be a shield can. For example, the first shielding structure 1710 may be formed of a metal or an alloy. The first shielding structure 1710 may be disposed to contact the ground portion (or ground pad) of the first substrate 410.

The second shielding structure 1720 may be formed of substantially the same material as the shielding structure 440 of FIG. 4. The second shielding structure 1720 may be disposed to contact the ground portion (or ground pad) of the second substrate 420.

According to an embodiment, the first shielding structure 1710 and the second shielding structure 1720 may be disposed to vertically overlap each other. For example, the first shielding structure 1710 may be disposed to contact the first substrate 410, and the second shielding structure 1720 may be disposed to contact the second substrate 420.

As illustrated in FIG. 17B, if the first substrate 410 and the second substrate 420 are assembled, the first shielding structure 1710 and the second shielding structure 1720 may be coupled to form the shielding area 1721. A filling material (e.g., the filling material 1850 of FIG. 18) to be described below may fill the shielding area 1721.

Even if a shield can is used in the multi-layered PCB assembly 1700, a second shielding structure 1720 may be used to fill the space between the shield can and the substrate.

FIG. 18 illustrates a state in which a filling material fills an inside of a printed circuit board assembly according to an embodiment.

The embodiment of FIG. 18 may be selectively combined with the embodiments of FIGS. 4 to 17B. The embodiment of FIG. 18 may be selectively combined with the embodiments of FIGS. 19A to 19D.

The multi-layered PCB assembly 1800 of FIG. 18 may be included in the electronic device (e.g., the electronic device 200 of FIG. 2A) of FIGS. 2A to 3. The multi-layered PCB assembly of FIG. 18 may be substantially the same as the PCB of FIG. 3 (e.g., the PCB 340 of FIG. 3).

Various types of electronic elements 1860 are illustrated in FIG. 18. In FIG. 18, the multi-layered PCB assembly 1800 may include a first substrate 1810, a second substrate 1820, a connection structure 1830, a shielding structure 1840, a filling material 1850, and a plurality of electronic elements 1860. The connection structure 1830 may include a first coupling portion 1831 and a second coupling portion 1832.

The first substrate 1810 may correspond to the first substrate of FIG. 4 (e.g., the first substrate 410 of FIG. 4). The second substrate 1820 may correspond to the second substrate of FIG. 4 (e.g., the second substrate 420 of FIG. 4). The connection structure 1830 may correspond to the connection structure of FIG. 4 (e.g., the connection structure 430 of FIG. 4). The shielding structure 1840 may correspond to the shielding structure of FIG. 4 (e.g., the shielding structure 1840 of FIG. 4).

According to an embodiment, the filling material 1850 may fill the shielding area 1841 formed by the shielding structure 1840. For example, the filling material 1850 may be an insulation material or a heat dissipation material. For example, the shielding area 1841 may be filled with a filling material 1850 formed of a thermal interface material (TIM) to easily dissipate heat emitted from multiple electronic elements 1860 to the outside.

The multi-layered PCB assembly 1800 according to an embodiment may fill the space between the stacked substrates by forming the shielding area 1841 of the separate shielding structure 1840, even if a connection structure 1830, such as a connector, which does not form a closed curve, is used.

FIGS. 19A to 19D illustrate a shielding structure applied to a multi-layered printed circuit board assembly having a multi-layer structure of three of more layers according to one or more embodiments.

The multi-layered PCB assemblies 1910 to 1930 shown in FIGS. 19A to 19D may be included in the electronic device of FIGS. 2A to 3 (e.g., the electronic device 200 of FIG. 2A). The embodiments of FIGS. 19A to 19D may be selectively combined with the embodiments of FIGS. 4 to 18.

FIGS. 19A to 19D illustrate example embodiments for describing shielding structures of various structures disposed on the multi-layered PCB assembly 1910, 1920, 1930 or 1940.

The shielding structures 1914, 1924, 1934, and 1945 (shown in FIGS. 19A to 19D) may be formed of substantially the same material as the shielding structure 440 of FIG. 4.

In FIG. 19A, the multi-layered PCB assembly 1910 may include a first substrate 1911, a second substrate 1912, a third substrate 1913, and a shielding structure 1914. The shielding structure 1914 may include a first shielding member 1914a and a second shielding member 1914b. The first shielding member 1914a may connect the first substrate 1911 and the second substrate 1912. The first shielding member 1914a may be disposed to shield spurious waves generated in the electronic element disposed between the first substrate 1911 and the second substrate 1912. The second shielding member 1914b may connect the second substrate 1912 and the third substrate 1913. The second shielding member 1914b may be disposed to shield spurious waves generated in the electronic element disposed between the second substrate 1912 and the third substrate 1913.

In FIG. 19B, the multi-layered PCB assembly 1920 may include a first substrate 1921, a second substrate 1922, a third substrate 1923, and a shielding structure 1924. The second substrate 1922 may be smaller than the first substrate 1921 and the third substrate 1923. The shielding structure 1924 may include a first shielding member 1924a and a second shielding member 1924b. The first shielding member 1924a may connect the first substrate 1921 and the second substrate 1922. The second shielding member 1924b may connect the first substrate 1921 and the third substrate 1923.

In FIG. 19C, the multi-layered PCB assembly 1930 may include a first substrate 1931, a second substrate 1932, a third substrate 1933, and a shielding structure 1934. The shielding structure 1934 may include a first shielding member 1934a, a second shielding member 1934b, and a third shielding member 1934c. The first shielding member 1934a may connect the first substrate 1931 and the second substrate 1932. The second shielding member 1934b may connect the second substrate 1932 and the third substrate 1933. The third shielding member 1934c may connect the first substrate 1931 and the third substrate 1933.

In FIG. 19D, the multi-layered PCB assembly 1940 may include a first substrate 1941, a second substrate 1942, a third substrate 1943, a fourth substrate 1944, and a shielding structure 1945. The shielding structure 1945 may include a first shielding member 1945a, a second shielding member 1945b, and a third shielding member 1945c. The first shielding member 1945a may connect the first substrate 1941 and the second substrate 1942. The second shielding member 1945b may connect the first substrate 1941 and the third substrate 43. The third shielding member 1945c may connect the third substrate 1943 and the fourth substrate 1944.

Even if the multi-layered PCB assembly 1910, 1920, 1930, or 1940 having a relatively complex structure as shown in FIGS. 19A to 19D is configured, a shielding area may be more easily formed as compared to a shield can or an interposer.

A multi-layered PCB assembly according to an embodiment of the disclosure may include a first substrate 410, 1810, a second substrate 420, 1820 above the first substrate 410, 1810, a plurality of connection structures 430, 1830 disposed between the first substrate 410, 1810 and the second substrate 420, 1820 and configured to connect the first substrate 410, 1810 and the second substrate 420, 1820, and a shielding structure 440, 1300, 1400, 1500, 1840 connected to a ground portion of the first substrate 410, 1810 and a ground portion of the second substrate 420, 1820 and disposed to form a closed area to shield electromagnetic interference of an electronic component disposed in the closed area.

According to an embodiment, the shielding structure 440, 1300, 1400, 1500, 1840 may be disposed so that the plurality of connection structures 430, 1830 are positioned outside the closed area formed by the shielding structure 440, 1300, 1400, 1500.

According to an embodiment, the shielding structure 440, 1300, 1400, 1500, 1840 may be disposed so that the plurality of connection structures 430, 1830 are positioned inside the closed area formed by the shielding structure 440, 1300, 1400, 1500.

According to an embodiment, the shielding structure 440, 1300, 1400, 1500, 1840 may connect a first connection structure of the plurality of connection structures 430, 1830 and a second connection structure of the plurality of connection structures 430, 1830. The closed area may be formed by the plurality of connection structures 430, 1830 and the shielding structure 440, 1300, 1400, 1500, 1840.

According to an embodiment, the shielding structure 440, 1300, 1400, 1500, 1840 and the plurality of connection structures 430, 1830 may be spaced apart from each other at a predetermined interval.

According to an embodiment, the shielding structure 440, 1300, 1400, 1500, 1840 may be configured to contact an upper surface of the first substrate 410, 1810 and a lower surface of the second substrate 420.

According to an embodiment, the shielding structure 440, 1300, 1400, 1500, 1840 may be configured to contact an upper side (e.g., surface) of the first substrate 410, 1810 and a lateral side (e.g., surface) of the second substrate 420.

According to an embodiment, the shielding structure 440, 1300, 1400, 1500, 1840 may be configured to contact a lateral side (e.g., surface) of the first substrate 410, 1810 and a lateral side (e.g., surface) of the second substrate 420.

According to an embodiment, the multi-layered PCB assembly may further include a filling material 1850 filling an area formed by the shielding structure 440, 1300, 1400, 1500, 1840, the first substrate 410, 1810, and the second substrate 420, 1820.

According to an embodiment, the filling material 1850 may include an insulation material or a heat dissipation material.

According to an embodiment, the shielding structure 440, 1300, 1400, 1500, 1840 may include an electrically conductive filler and a binder resin.

According to an embodiment, a first portion of the shielding structure 440, 1300, 1400, 1500, 1840 may be printed on one of the first substrate 410, 1810. A second portion of the shielding structure 440, 1300, 1400, 1500, 1840 may be configured to contact the second substrate by thermal curing.

An electronic device according to an embodiment may include a housing, a first substrate 410, 1810 disposed in the housing, a second substrate 420, 1820 in the housing and being above the first substrate 410, 1810, a plurality of connection structures 430, 1830 disposed between the first substrate 410, 1810 and the second substrate 420, 1820 and configured to connect the first substrate 410, 1810 and the second substrate 420, 1820, and a shielding structure 440, 1300, 1400, 1500, 1840 connected to a first ground portion of the first substrate 410, 1810 and a second ground portion of the second substrate 420, 1820 and disposed to form a closed area to shield electromagnetic interference of an electronic component disposed in the closed area.

According to an embodiment, the plurality of connection structures 430, 1830 are positioned outside the closed area formed by the shielding structure 440, 1300, 1400, 1500, 1840.

According to an embodiment, the plurality of connection structures 430, 1830 are positioned inside the closed area formed by the shielding structure 440, 1300, 1400, 1500, 1840.

According to an embodiment, the shielding structure 440, 1300, 1400, 1500, 1840 may connect a first connection structure of the plurality of connection structures 430, 1830 and a second connection structure of the plurality of connection structures 430, 1830. The plurality of connection structures 430, 1830 may be configured to form the closed area.

According to an embodiment, the shielding structure 440, 1300, 1400, 1500, 1840 and the plurality of connection structures 430, 1830 may be spaced apart from each other at a predetermined interval.

According to an embodiment, the shielding structure 440, 1300, 1400, 1500, 1840 may include an electrically conductive filler and a binder resin.

According to an embodiment, the electronic device may further include a filling material 1850 filling an area formed by the shielding structure 440, 1300, 1400, 1500, 1840, the first substrate 410, 1810, and the second substrate 420, 1820.

According to an embodiment, the filling material 1850 may include an insulation material or a heat dissipation material.

The terms as used herein are provided merely to describe some embodiments thereof, but are not intended to limit the disclosure. As used herein, the singular forms “a,” “an,” and “the” are intended to include the plural forms as well, unless the context clearly indicates otherwise. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, the term ‘and/or’ should be understood as encompassing any and all possible combinations by one or more of the enumerated items. As used herein, the terms “include,” “have,” and “comprise” are used merely to designate the presence of the feature, component, part, or a combination thereof described herein, but use of the term does not exclude the likelihood of presence or adding one or more other features, components, parts, or combinations thereof. As used herein, the terms “first” and “second” may modify various components regardless of importance and/or order and are used to distinguish a component from another without limiting the components.

As used herein, the terms “configured to” may be interchangeably used with the terms “suitable for,” “having the capacity to,” “designed to,” “adapted to,” “made to,” or “capable of” depending on circumstances. The term “configured to” does not essentially mean “specifically designed in hardware to.” Rather, the term “configured to” may mean that a device can perform an operation together with another device or parts. For example, a ‘device configured (or set) to perform A, B, and C’ may be a dedicated device to perform the corresponding operation or may mean a general-purpose device capable of various operations including the corresponding operation.

Meanwhile, the terms “upper side”, “lower side”, and “front and rear directions” used in the disclosure are defined with respect to the drawings, and the shape and position of each component are not limited by these terms.

In the disclosure, the above-described description has been made mainly of specific embodiments, but the disclosure is not limited to such specific embodiments, but should rather be appreciated as covering all various modifications, equivalents, and/or substitutes of one or more embodiments.

What is claimed is:

1. A multi-layered printed circuit board assembly, comprising:
a first substrate;
a second substrate above the first substrate;
a plurality of connection structures between the first substrate and the second substrate, the plurality of connection structures being configured to connect the first substrate and the second substrate; and
a shielding structure connected to a ground portion of the first substrate and a ground portion of the second substrate,
wherein the shielding structure is configured to form a closed area to shield electromagnetic interference of an electronic component in the closed area.

2. The multi-layered printed circuit board assembly of claim 1, wherein the plurality of connection structures are positioned outside the closed area formed by the shielding structure.

3. The multi-layered printed circuit board assembly of claim 1, wherein the plurality of connection structures are positioned inside the closed area formed by the shielding structure.

4. The multi-layered printed circuit board assembly of claim 1, wherein the shielding structure is configured to connect a first connection structure of the plurality of connection structures and a second connection structure of the plurality of connection structures, and
wherein the plurality of connection structures are configured to form the closed area.

5. The multi-layered printed circuit board assembly of claim 4, wherein the shielding structure and the plurality of connection structures are spaced apart from each other at a predetermined interval.

6. The multi-layered printed circuit board assembly of claim 1, wherein the shielding structure is configured to contact an upper side of the first substrate and a lower side of the second substrate.

7. The multi-layered printed circuit board assembly of claim 1, wherein the shielding structure is configured to contact an upper side of the first substrate and a lateral side of the second substrate.

8. The multi-layered printed circuit board assembly of claim 1, wherein the shielding structure is configured to contact a lateral side of the first substrate and a lateral side of the second substrate.

9. The multi-layered printed circuit board assembly of claim 1, further comprising a filling material filling an area formed by the shielding structure, the first substrate, and the second substrate.

10. The multi-layered printed circuit board assembly of claim 9, wherein the filling material comprises an insulation material or a heat dissipation material.

11. The multi-layered printed circuit board assembly of claim 1, wherein the shielding structure comprises an electrically conductive filler and a binder resin.

12. The multi-layered printed circuit board assembly of claim 1, wherein a first portion of the shielding structure is printed on one of the first substrate, and wherein a second portion of the shielding structure is configured to contact the second substrate by thermal curing.

13. An electronic device comprising:
a housing;
a first substrate in the housing;
a second substrate in the housing, the second substrate being above the first substrate;
a plurality of connection structures between the first substrate and the second substrate, the plurality of connection structures being configured to connect the first substrate and the second substrate; and
a shielding structure connected to a first ground portion of the first substrate and a second ground portion of the second substrate,
wherein the shielding structure is configured to form a closed area to shield electromagnetic interference of an electronic component in the closed area.

14. The electronic device of claim 13, wherein the plurality of connection structures are positioned outside the closed area formed by the shielding structure.

15. The electronic device of claim 13, wherein the plurality of connection structures are positioned inside the closed area formed by the shielding structure.

16. The electronic device of claim 13, wherein the shielding structure is configured to connect a first connection structure of the plurality of connection structures and a second connection structure of the plurality of connection structures, and
wherein the plurality of connection structures are configured to form the closed area.

17. The electronic device of claim 16, wherein the shielding structure and the plurality of connection structures are spaced apart from each other at a predetermined interval.

18. The electronic device of claim 13, wherein the shielding structure comprises an electrically conductive filler and a binder resin.

19. The electronic device of claim 13. further comprising a filling material filling an area formed by the shielding structure, the first substrate, and the second substrate.

20. The electronic device of claim 19, wherein the filling material comprises an insulation material or a heat dissipation material.
